(19) United States
(12) Patent Application Publication
(10) Pub. No.: US 2016/0345425 A1
(43) Pub. Date: Nov. 24, 2016

(54) WIRING FILM FOR FLAT PANEL DISPLAY

(71) Applicant: Kabushiki Kaisha Kobe Seiko Sho (Kobe Steel, Ltd.), Kobe-shi (JP)

(72) Inventors: Hiroshi GOTO, Kobe-shi (JP); Yumi IWANARI, Kobe-shi (JP)

(73) Assignee: Kabushiki Kaisha Kobe Seiko Sho (Kobe Steel, Ltd.), Kobe-shi (JP)

(21) Appl. No.: 15/112,325

(22) PCT Filed: Jan. 21, 2015
(86) PCT No.: PCT/JP2015/051561

§ 371 Date: Jul. 18, 2016

(30) Foreign Application Priority Data
Feb. 7, 2014 (JP) 2014-022822

(51) Int. Cl. H05K 1/02; C23C 14/34; H01L 27/12; C23C 14/18; C23C 14/58; H05K 1/03; C22C 21/00; C23C 14/35

(52) U.S. Cl. CPC H05K 1/0207; C22C 21/00; C23C 14/3414; C23C 14/35; C23C 14/185; C23C 14/5806; C23C 14/5873; H05K 1/03; H01L 27/124

(57) ABSTRACT

This wiring film for a flat panel display comprises a laminate structure which is formed by laminating a first layer, which includes at least one type of high melting-point metal selected from the group consisting of Mo, Ti, Cr, W, and Ta, and a second layer, which comprises an Al alloy that includes at least 0.01 atom % but less than 0.2 atom % of at least one from among the rare earth elements, Ni, and Co. In this wiring film, even when subjected to a thermal history of high temperatures from 400-500° C., inclusive, increase in wiring resistance is suppressed, hillocks or the like do not occur, and heat resistance is excellent.

### TECHNICAL FIELD

The present invention relates to a wiring film for a flat panel display.

### BACKGROUND ART

Aluminum thin films having low electrical resistivity have been used as wiring films used for electrode materials for flat panel displays, such as liquid crystal displays, organic EL displays, and touch panels. However, Al has a low melting point and low heat resistance. Furthermore, Al is oxidized in air and, as a result, easily forms a passive film. Therefore, even if an Al thin film is directly connected to a semiconductor layer or a transparent pixel electrode, an insulating layer of aluminum oxide formed at the interface therebetween increases contact resistance, which disadvantageously reduces the display quality of a screen.

Such a problem has been solved by taking the following measure. First, in order to improve heat resistance, a laminate structure is formed by laminating the surface of Al with a barrier metal layer formed of a high-melting-point metal, such as Mo, Ti, Cr, W, or Ta. The lamination with a barrier metal layer having high mechanical strength suppresses hemispherical protrusions, called hillocks, produced as a result of stress concentration due to a difference in the thermal expansion coefficient between a substrate and Al. Another reason for interposing the barrier metal layer between the Al thin film and the semiconductor layer or the transparent pixel electrode is to prevent formation of aluminum oxide and enable electrical connection. Specifically, a laminate wiring thin film in which the barrier metal layer is formed on at least one of the upper and lower sides of the Al thin film is used.

With a request for high-definition flat panel displays that consume low power, materials for thin film transistors (TFTs) used as a switching matrix have also been studied. For example, amorphous silicon semiconductors used in the related art have been replaced by, for example, polysilicon semiconductors, such as a low-temperature-polysilicon semiconductor, and oxide semiconductors for the purpose of improving the performance. Since these semiconductor materials have a high carrier mobility and a large optical band gap and can be formed into a film at low temperatures, these materials are expected to be applied to, for example, resin substrates having low heat resistance and next-generation displays, which require a large size, high resolution, and high-speed driving.

A low-temperature-polysilicon semiconductor is generally produced by subjecting a semiconductor thin film formed of non-monocrystalline amorphous silicon or microcrystalline silicon to crystallization annealing at about 400 to 500° C., and a heating process, such as activation annealing, after impurity implantation. Specifically, for example, a semiconductor thin film of for example, amorphous silicon or microcrystalline silicon with a particle size of about 0.1 μm or less, which is relatively small, the semiconductor thin film being formed on a substrate by a CVD method, is irradiated with a laser beam. The semiconductor thin film is locally heated by irradiation with the laser beam and at least partially melted. In the cooling process after irradiation, the semiconductor thin film is then crystallized to form a polycrystal having a particle size of about 0.3 μm or more, which is relatively large. Crystallization annealing by such laser beam irradiation enables low-temperature processing of a thin film semiconductor device and allows use of not only an expensive quartz substrate having high heat resistance but also an inexpensive glass substrate. Activation annealing promotes bonding between Si and the impurity implanted in the polysilicon thin film, controls the carrier concentration, and recovers the crystal damaged by ion implantation.

Since producing a low-temperature polysilicon thus involves exposure to a thermal history at about 400 to 500° C. for crystallization annealing or activation annealing, the process temperature is relatively higher than that for amorphous silicon.

In oxide semiconductors, crystalline film properties are also obtained by laser annealing or high-temperature annealing at about 350 to 500° C., which improves performances, such as semiconductor mobility and threshold voltage of TFTs.

Since a thermal history applied during the process for producing TFTs formed of amorphous silicon known in the related art is up to about 350° C., the wiring thin film in which an Al thin film is laminated with a high-melting-point metal can be used without any problems. However, when a semiconductor material exposed to a thermal history at about 400 to 500° C., such as a low-temperature polysilicon or an oxide semiconductor, is applied to TFTs, this thermal history at high temperatures causes mutual diffusion between Al and the high-melting-point metal, such as Mo, and leads to a problem associated with, for example, an increase in wiring resistance. Alternatively, the thermal history at high temperatures increases the stress of the substrate and the wiring thin film, and generates hillocks on the surface of the wiring thin film as a result of promoted stress diffusion of Al such that Al penetrates into the high-melting-point metal. In addition, problems associated with, for example, formation of side hillocks also arise on part of the side-wall portions of the wiring thin film, the part having no coating with the high-melting-point metal. In this way, the heat treatment at 400° C. or higher requires a wiring film that deals with a behavior different from that in a heat treatment at lower than 400° C.

Therefore, when a low-temperature polysilicon, an oxide semiconductor, or the like is applied to a semiconductor layer in a TFT, a monolayer wiring thin film formed of a high-melting-point metal has been used instead of a laminate wiring film that includes a high-melting-point metal and an Al thin film and is used when amorphous silicon is used. However, the high-melting-point metal has a high electrical resistivity.

The inventors of the present invention have disclosed, in PTL 1, an Al-alloy film containing at least one of Nd, Gd, and Dy in a total amount of more than 1.0 at % and 15 at % or less as a heat-resistant wiring material that has heat resistance up to 400° C., namely, effectively prevents hillock formation.

### CITATION LIST

### Patent Literature

PTL 1: Japanese Patent No. 2733006

### SUMMARY OF INVENTION

### Technical Problem

However, PTL 1 is directed to a technique targeted for amorphous silicon. That is, PTL 1 aims to realize heat resistance and low specific resistance in a heating process at about 250 to 400° C. after electrode film formation, which is essential to a TFT production process, and does not aim to improve the above properties at a temperature higher than about 400° C.

The present invention has been made under such circumstances. An object of the present invention is to provide a wiring film for a flat panel display. The wiring film has good heat resistance such that an increase in wiring resistance is suppressed and no hillocks or other defects are formed even after the wiring film is subjected to a thermal history at a high temperature of 400° C. or higher and 500° C. or lower.

### Solution to Problem

The wiring film for a flat panel display, the wiring film being obtained by solving the above-mentioned problem, is a wiring film for a flat panel display, the wiring film being a film to be formed on a substrate. The wiring film has a laminate structure including a first layer, which includes at least one high-melting-point metal selected from the group consisting of Mo, Ti, Cr, W, and Ta, and a second layer, which includes an Al alloy that contains at least one of rare earth elements, Ni, and Co in an amount of 0.01 at % or more and less than 0.2 at %.

In a preferred embodiment, the wiring film for a flat panel display further includes a reaction layer including Al and at least one of the high-melting-point metals at the interface between the first layer and the second layer.

In a preferred embodiment of the present invention, the Al alloy contains a rare earth element in an amount of 0.01 at % or more and at least one of Ni and Co in an amount of 0.01 at % or more.

In a preferred embodiment of the present invention, the reaction layer is formed by a thermal history at 400° C. or higher and 500° C. or lower.

In a preferred embodiment of the present invention, the rare earth elements include at least one selected from the group consisting of Nd, La, Gd, Dy, Y, and Ce.

In a preferred embodiment of the present invention, the reaction layer includes a compound of Al and Mo.

In a preferred embodiment of the present invention, the wiring film has a laminate structure in which the first layer and the second layer are formed in this order from the substrate side, or the wiring film has a laminate structure in which the second layer and the first layer are formed in this order from the substrate side.

In a preferred embodiment of the present invention, the wiring film has a laminate structure in which the first layer, the second layer, and the first layer are formed in this order from the substrate side. Each of the reaction layers is formed at each interface between the first layer and the second layer.

### Advantageous Effects of Invention

According to the present invention, a wiring film for a flat panel display is provided. The wiring film has low wiring resistance and high heat resistance such that an increase in electrical resistivity is suppressed and no hillocks or other defects are formed even after the wiring film is subjected to a thermal history at a high temperature of 400° C. or higher and 500° C. or lower.

### BRIEF DESCRIPTION OF DRAWINGS

FIG. 1 illustrates a scanning electron microscope image of the cross section of Example No. 1.

FIG. 2 illustrates a scanning electron microscope image of the cross section of Example No. 2.

FIG. 3 illustrates a scanning electron microscope image of the cross section of Example No. 3.

FIG. 4 illustrates a scanning electron microscope image of the cross section of Example No. 4.

FIG. 5 illustrates a transmission electron microscope image of the cross section of Example No. 1.

FIG. 6 illustrates a transmission electron microscope image of the cross section of Example No. 2.

FIG. 7 illustrates a transmission electron microscope image of the cross section of Example No. 4.

FIG. 8 illustrates the relationship between the heat treatment temperature and the electrical resistivity of various laminate wiring films having a three-layer structure according to Examples.

### DESCRIPTION OF EMBODIMENTS

The inventors have diligently carried out studies in order to provide a wiring film for a flat panel display. The wiring film has good heat resistance such that an increase in wiring resistance is suppressed and no hillocks or other defects are formed even after the wiring film is subjected to a thermal history at a high temperature of 400° C. or higher and 500° C. or lower. As a result, it has been found that such an object is achieved when a wiring film having a laminate structure including Al wiring and a high-melting-point metal layer formed of Mo or the like includes, as an Al wiring material, an Al alloy containing at least one alloy element selected from Ni, Co, and rare earth elements (hereinafter may be referred to as “REMs” (rare earth metals)), such as Nd, La, Gd, Dy, Y, and Ce, in an amount much lower than that in the related art. That is, the present invention is completed based on the following findings: the heat resistance is effectively improved by addition of the alloy element, and a reaction layer, which functions as a barrier layer that prevents mutual diffusion between Al and a high-melting-point metal, is formed at the interface between Al and the high-melting-point metal, which reduces the density of grain boundaries, which serve as diffusion paths, and thus suppresses an increase in wiring resistance.

It has been found that the mutual diffusion between the Al wiring and the high-melting-point metal, such as Mo, increases and the wiring resistance increases at a higher rate as the Al wiring has a finer structure and has a higher density of grain boundaries. Pure Al has the coarsest structure and a low density of grain boundaries, but has poor heat resistance. Because of such properties, side hillocks are formed on pure Al as described below in Examples when pure Al is subjected to a thermal history at 400° C. or higher with pure Al laminated with a high-melting-point metal. When side hillocks are formed, the side hillocks penetrate into at least one of a gate insulating film and a protective film, which is an upper film, and thus cause leakage of currents, resulting in deterioration in the properties of TFT elements.

Therefore, the inventors have focused on alloy elements in order to obtain an Al alloy that has good heat resistance and can suppress an increase in wiring resistance due to mutual diffusion between a high-melting-point metal and Al wiring. As a result, an Al alloy containing at least one of rare earth elements, Ni, and Co in a total amount, of less than 0.2 at % is found to have a structure with relatively large crystal grains, which is similar to those of pure Al, and thus have a low density of grain boundaries.

Application of a thermal history at a high temperature of 400° C. or higher to the Al alloy causes grain boundary diffusion, which is diffusion of a high-melting-point metal from a first layer to a second layer mainly through Al grain boundaries. The first layer includes the high-melting-point metal and contacts the second layer, which includes the Al alloy. In Al alloys, grain boundary diffusion, which is diffusion through grain boundaries, is more likely to occur than intragrain diffusion, which is diffusion inside crystal grains. For this reason, when an Al alloy in which the total amount of alloy elements is significantly reduced as defined in the present invention and described above is used, the grain boundary diffusion slightly proceeds, but formation of a reaction layer including at least Al and a high-melting-point metal proceeds at the interface between the first layer and the second layer while competing with the grain boundary diffusion. As a result, this competition is ended up with preceding formation of the reaction layer at the interface. This reaction layer effectively functions as a barrier layer for preventing mutual diffusion between Al and the high-melting-point metal and terminates the grain boundary diffusion. As a result, an increase in wiring resistance is suppressed.

The wiring film of the present invention has a laminate structure including a first layer, which includes at least one high-melting-point metal selected from the group consisting of Mo, Ti, Cr, W, and Ta, and a second layer, which includes an Al alloy that contains, as an alloy element, at least one of rare earth elements, Ni, and Co in an amount of 0.01 at % or more and less than 0.2 at %.

First, the Al alloy forming the second layer, by which the wiring film is most characterized, will be described.

### [At Least One of Rare Earth Elements, Ni, and Co in Amount of 0.01 at % or More and Less Than 0.2 at %]

Rare earth elements, Ni, and Co, which are elements contributing to an improvement in the heat resistance of Al, further contribute to an improvement in heat resistance at 400° C. or higher and 500° C. or lower when laminated together with the first layer as described below.

The term “rare earth elements” as used herein refers to Sc, Y, and lanthanide elements including 15 elements from La to Lu. Preferred rare earth elements are Nd, La, Gd, Dy, Y, and Ce. These elements may be used alone or in combination of two or more. More preferred are Nd, La, Gd, and Dy, and still more preferred are Nd and La.

In order to obtain the above effect, at least one alloy element selected from these rare earth elements, Ni, and Co in an amount of 0.01 at % or more needs to be added to the Al alloy of the present invention. The amount of at least one alloy element is preferably 0.02 at % or more and more preferably 0.05 at % or more.

A larger amount of the alloy element is more preferred in order to improve heat resistance. However, an excess amount of the alloy element results in small crystal grains and accordingly results in an increased density of grain boundaries, which increases the amount of the high-melting-point metal diffused into the second layer through grain boundaries and thus significantly increases wiring resistance. Therefore, the total amount of the alloy element in the Al alloy needs to be less than 0.2 at %, preferably 0.15 at % or less, and more preferably 0.12 at % or less.

The amount of the rare earth element is preferably 0.01 at % or more in order to obtain a great effect of improving heat resistance. The acceptable upper limit of the amount of the rare earth element is less than 0.2 at %, which is the upper limit of the amount of the alloy element from the viewpoint of heat resistance. The amount of the rare earth element is preferably 0.05 at % or less in order to further reduce the wiring resistance at 400° C. or higher and 500° C. or lower. The amount of the rare earth element is more preferably 0.02 at % or more, still more preferably 0.035 at % or more, and more preferably 0.15 at % or less, still more preferably 0.10 at % or less. The term “amount of the rare earth element” as used herein refers to the amount of a single rare earth element when the rare earth element is used alone, and refers to the total amount of two or more rare earth elements when the rare earth elements are used in combination.

In order to obtain a sufficient effect of improving heat resistance and a sufficient effect of suppressing an increase in wiring resistance, the amount of at least one of Ni and Co (hereinafter, may be referred to simply as “ at least one of Ni and Co”) is preferably 0.01 at % or more, more preferably 0.02 at % or more. The acceptable upper limit of the amount of at least one of Ni and Co is less than 0.2 at %, which is the upper limit of the amount of the alloy element from the viewpoint of heat resistance. Since an excess amount of at least one of Ni and Co results in increased wiring resistance, the amount of at least one of Ni and Co is preferably 0.1 at % or less, and more preferably 0.08 at % or less. Nickel and cobalt may be added alone or in combination. The amount of at least one of Ni and Co refers to the amount of Ni or Co when either Ni or Co is contained and refers to the total amount, of Ni and Co when both Ni and Co are contained.

In the present invention, these alloy elements may be added alone or in combination of two or more. An effect of improving heat resistance is obtained as long as the Al alloy contains the alloy element(s) in the above range. In order to obtain a great effect of improving heat resistance, the Al alloy preferably contains a rare earth element and at least one of Ni and Co.

The Al alloy used in the present invention contains at least one of rare earth elements, Ni, and Co in an amount of 0.01 at % or more and less than 0.2 at % as described above, with the balance being Al and inevitable impurities. Preferably, the Al alloy contains a rare earth element and at least one of Ni and Co, with the balance being Al and inevitable impurities.

The Al alloy of the present invention may further contain (i) at least one selected from the group consisting of Mo, Ti, Cr, W, and Ta; and (ii) at least one of Cu and Ge unless advantages of the present invention are impaired.

(i) At least one selected from the group consisting of Mo, Ti, Cr, W, and Ta increases the heat resistance of the Al alloy and effectively prevents formation of hillocks and aluminum oxide in a thermal history at a high temperature of 400° C. or higher and 500° C. or lower. In order to obtain such effects, the amount of at least one selected from the group consisting of Mo, Ti, Cr, W, and Ta is preferably 0.01 at % or more, and more preferably 0.02 at % or more. When the amount of these alloy elements is small, specifically, preferably less than 0.05 at %, and more preferably 0.03 at % or less, low wiring resistance is achieved with the Al alloy. Furthermore, formation of the reaction layer can suppress diffusion of the high-melting-point metal from the first layer through Al grain boundaries and thus can suppress an increase in wiring resistance due to mutual diffusion. These alloy elements may be added alone or in combination of two or more. The amount of an alloy element refers to the amount of a single alloy element when any of these alloy elements is contained alone and refers to the total amount of alloy elements when multiple alloy elements are contained.

(ii) Copper and germanium are elements that precipitate at a temperature lower than those at which the above-mentioned rare earth elements, Ni, and Co precipitate. Copper and germanium have no adverse effect on the density of grain boundaries and thus suppress an increase in wiring resistance. In order to obtain such an effect, the amount of at least one of Cu and Ge is preferably 0.01 at % or more, and more preferably 0.02 at % or more. However, since an excess amount of at least one of Cu and Ge results in increased wiring resistance, the amount of at least one of Cu and Ge is preferably 0.05 at % or less, and more preferably 0.03 at % or less. Copper and germanium may be added alone or in combination. The amount of at least one of Cu and Ge refers to the amount of Cu or Ge when either Cu or Ge is contained and refers to the total amount of Cu and Ge when both Cu and Ge are contained.

Even when the Al alloy contains (i) at least one selected from the group consisting of Mo, Ti, Cr, W, and Ta; and (ii) at least one of Cu and Ge, the total amount of alloy elements in the Al alloy, namely, rare earth elements, Ni, Co, the elements (i) and (ii) needs to be controlled at less than 0.2 at %. When the total amount is 0.2 at % or more, a problem related to, for example, increased wiring resistance after heating arises. The preferred range of the total amount is as described above.

The wiring layer of the present invention will be described below.

The wiring film of the present invention has a laminate structure including a first layer, which includes at least one high-melting-point metal selected from the group consisting of Mo, Ti, Cr, W, and Ta, and a second layer, which includes the Al alloy. Specifically, the wiring film may have a two-layer structure in which the first layer and the second layer are laminated in this order from the substrate side, or may have a two-layer structure in which the second layer and the first, layer are laminated in this order from the substrate side. Alternatively, the wiring film may have a three-layer structure in which the first layer is disposed on each of the upper and lower surfaces of the second layer. That is, the wiring film may have a three-layer structure in which the first layer, the second layer, and the first layer are laminated in this order from the substrate side. In the present invention, in the three-layer structure, the first layer laminated on the second layer opposite the substrate may be referred to as a third layer.

In particular, the wiring film preferably has a three-layer structure because the oxidation resistance of the Al alloy, which is the second layer, is improved and the heat resistance of the Al alloy is improved.

The high-melting-point metals used in the first layer of the present invention are typically used for a barrier layer in the technical field of flat displays. Specifically, the high-melting-point metals may be used as alloy elements including one or more of Mo, Ti, Cr, W, and Ta. When the first layer is disposed on each of the upper and lower surfaces of the second layer, the upper first layer and the lower first layer may have the same composition or may have different compositions. The first layers may include elements other than the high-melting-point metals, but preferably includes any of the high-melting-point, metals, with the balance being inevitable impurities.

The wiring film of the present invention having any of the laminate structures includes a reaction layer including Al and a high-melting-point metal and formed at the interface between the first layer and the second layer. When the wiring film has a three-layer structure, the wiring film further includes another reaction layer formed at the interface between the second layer and the third layer. The term “reaction layer” as used herein refers to a layer formed by a thermal history at a high temperature to which a low-temperature polysilicon or an oxide semiconductor is exposed, preferably at 400° C. or higher and 500° C. or lower. When the maximum temperature of the thermal history is set to 500° C. or lower, the reaction layer no longer grows and stays at the interface, which effectively suppresses an increase in electrical resistance. The reaction layer includes, for example, a compound of Al and a high-melting-point metal, specifically, a compound of Al and Mo.

The reaction layer can be checked by observing the cross section of the wiring film, which has a laminate structure and is obtained after a heat treatment, under a transmission electron microscope (hereinafter may be referred to as a “TEM”) as shown in Examples.

The substrate used in the present invention is any substrate that is usually used in the field of flat panel displays. Examples of the substrate include those made of, for example, glass, quartz, silicon, and metals, such as SUS and Ti foil.

A flat panel display of the present invention includes the wiring film of the present invention as described above. Examples of the flat panel display include a liquid crystal display, an organic EL display, a touch panel, a field emission display, a vacuum fluorescent display, and a plasma display.

In the flat panel display, a semiconductor layer of a thin film transistor is preferably formed of a low-temperature polysilicon or an oxide. As described above, these materials may be subjected to a thermal history at a high temperature of 400° C. or higher and 500° C. or lower during the production process or in order to improve the film properties. The use of the wiring film according to the present invention ensures maximum advantages of these semiconductor layer materials without, any adverse effect on heat resistance or wiring resistance. The oxide is not limited, and an example oxide is an oxide of at least one element selected from the group consisting of Tn, Zn, Ga, and Sn, which are commonly used.

The Al-alloy thin film by which the present invention is characterized is preferably formed by using a sputtering target (hereinafter may be referred to as a “target”) in a sputtering method. An example method for forming the thin film is an ink-jet coating method, a vacuum deposition method, or a sputtering method. Of these, a sputtering method is preferred because of ease of alloying and film thickness uniformity.

When the Al-alloy film is formed by the sputtering method, an Al-alloy sputtering target containing a predetermined amount of at least one of rare earth elements, Ni, and Co and having the same composition as a desired Al-alloy film is used as the sputtering target. The use of such an Al-alloy sputtering target enables formation of an alloy film having a desired composition without a risk of composition unevenness. Alternatively, co-deposition may be performed by using multiple sputtering targets in order to form an Al-alloy film having a desired composition.

A sputtering target used to form a first, wiring film is an Al-alloy sputtering target containing at least one of rare earth elements, Ni, and Co in an amount of 0.01 at % or more and less than 0.2 at %, with the balance being Al and inevitable impurities. The Al-alloy sputtering target preferably contains a rare earth element(s) in an amount of 0.01 at % or more and at least one of Ni and Co in an amount of 0.01 at % or more, with the total amount of alloy elements being less than 0.2 at %, and with the balance being Al and inevitable impurities.

The sputtering target may further contain (i) at least one selected from the group consisting of Mo, Ti, Cr, W, and Ta; and (ii) at least one of Cu and Ge in the amounts described above unless advantages of the present invention are impaired.

An example method for producing the sputtering target is a vacuum melting method or a powder sintering method. Producing the sputtering target by a vacuum melting method is particularly preferred from the viewpoint of the composition in the target surface and the uniformity of the structure.

The wiring resistance of the wiring film according to the present invention differs depending on the structure of a flat panel display, wiring rules, and the like. The electrical resistivity is substantially 5.5 μΩcm or less, and preferably 5.0 μΩcm or less.

This application claims the benefit of Japanese Patent Application No. 2014-022822, filed Feb. 7, 2014, the entirety of which is incorporated herein by reference.

### EXAMPLES

The present invention will be described below in more detail by way of Examples, which should not be construed as limiting the present invention. It is to be understood that variations and modifications can be made to practice the present invention without departing from the spirit of the present invention. Such variations and modifications are within the technical scope of the present invention.

### Experiment 1 (Evaluation of Heat Resistance)

A glass substrate was laminated with a first layer formed of Mo and having a thickness of 70 nm, a second layer formed of an Al—Ni—La alloy with the composition shown in Table 1 and having a thickness of 300 nm, and a first layer formed of Mo and having a thickness of 70 nm (hereinafter referred to as a “third layer”) in this order from the substrate side by a sputtering method. The second layers in Example Nos. 2 to 4 were deposited by using sputtering targets having corresponding compositions. At this time, the DC power ratio was controlled so as to obtain the composition of the second layer shown in Table 1. The second layer in Example No. 1 was a pure-Al film having a thickness of 300 nm, which was formed by using a pure-Al sputtering target. The composition of the second layer was determined by quantitative analysis with an ICP emission spectrophotometer. In Table, at % means atomic percent.

The sputtering conditions are as described below.

DC Magnetron Sputtering System

Target size: 4 inch φ×5 mmt

Ar gas pressure: 2 mTorr

DC power: 250 W

Distance between electrodes: 100 mm

Substrate temperature: Room temperature

Next, a line-and-space pattern with a width of 5 μm was formed by lithography and etching, followed by a heat treatment at temperatures of 400° C. and 450° C. for 1 hour in a nitrogen atmosphere by performing infrared heating.

The obtained samples were evaluated for their heat resistance. Specifically, the presence of side hillocks was checked by observing the cross section of each sample in an obliquely upward direction of laminate wiring under a scanning electron microscope (SEM) after the heat treatment. The magnification was in the range of 3000× to 10000×. The samples with formation of side hillocks were rated A and the samples without formation of side hillocks were rated B. The results are shown in Table 1.

TABLE 1

| | | Presence of | |
|---|---|---|---|
| | | hillock formation | |
| No. | First layer/Second layer/Third layer | 400° C. | 450° C. |
| 1 | Mo/Al/Mo | A | A |
| 2 | Mo/Al•0.02 at % Ni•0.035 at % La/Mo | B | B |
| 3 | Mo/Al•0.04 at % Ni•0.07 at % La/Mo | B | B |
| 4 | Mo/Al•0.08 at % Ni•0.14 at % La/Mo | B | B |

As shown in Table 1, no side hillocks were found to be formed in Example Nos. 2 to 4 at any heating temperature. No side hillocks were found either in a wiring end.

In Example No. 1, protrusions, called side hillocks, were found to be densely formed in a wiring end at both heating temperatures.

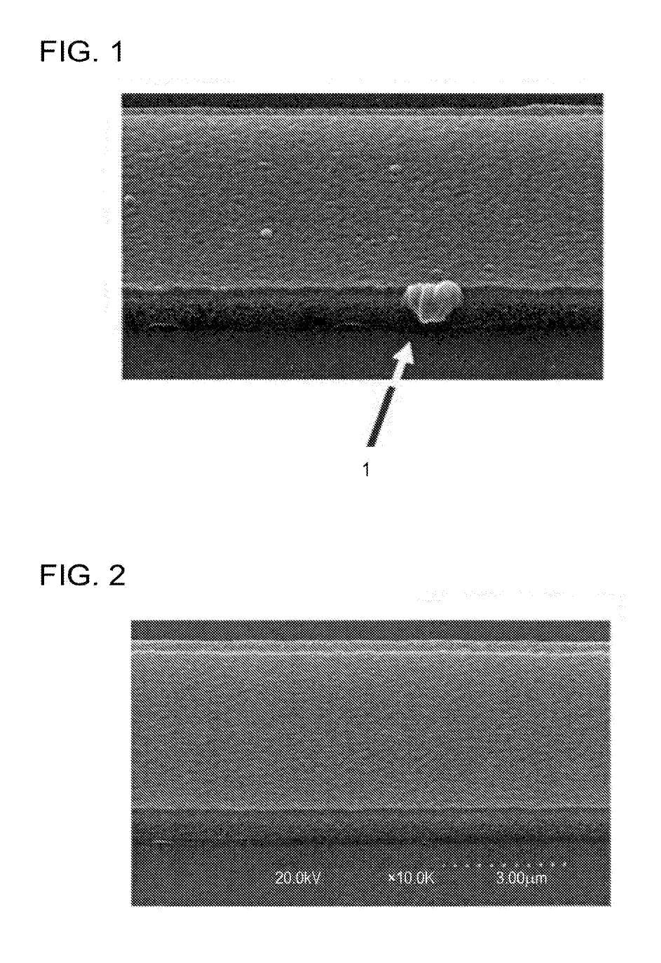

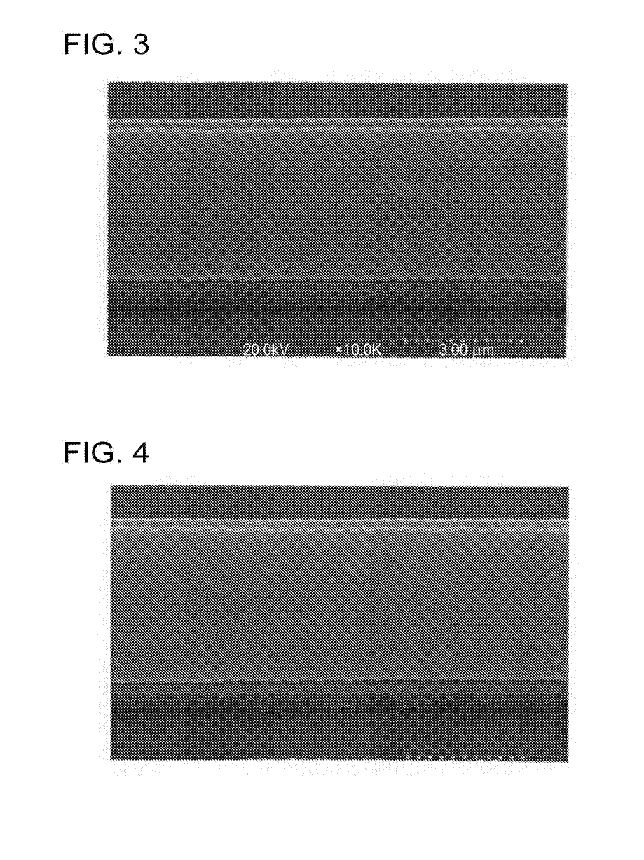

FIGS. 1 to 4 illustrate SEM images of Example Nos. 1 to 4 after these samples were heated to 450° C. FIG. 1 shows that a protrusion 1 corresponding to a side hillock was formed on a wiring end. In contrast, FIGS. 2 to 4 show that no protrusion was formed in Example Nos. 2 to 4.

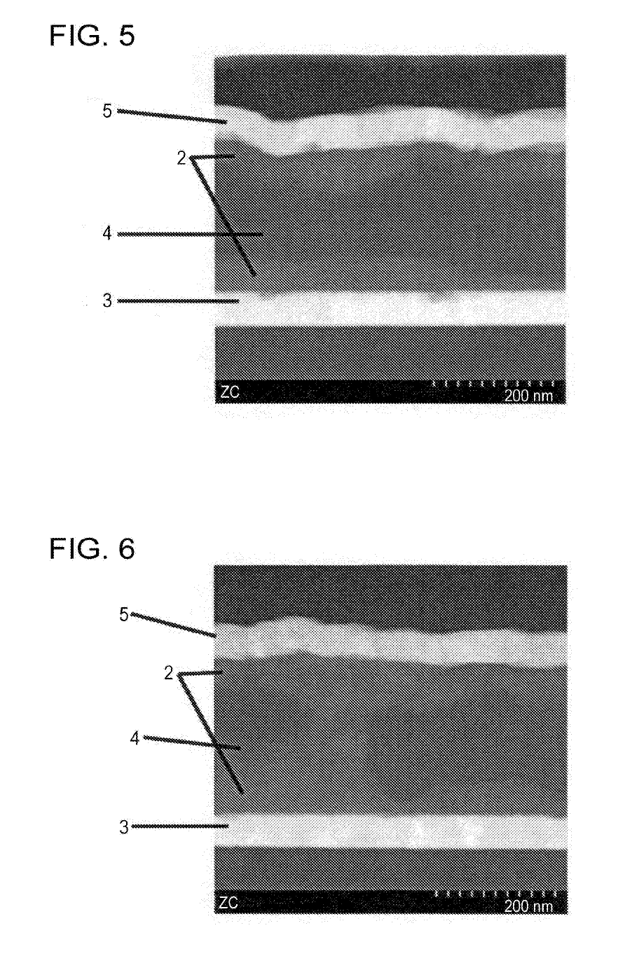

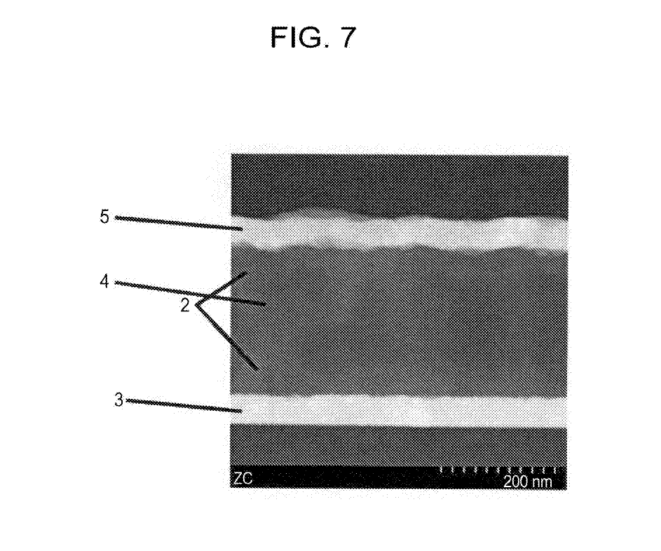

FIGS. 5 to 7 illustrate the TEM dark field image of the cross section of the laminate wiring observed after the laminate wiring was further heated to 450° C. FIGS. 5 to 7 show that Mo—Al reaction layers 2 are formed between a first layer 3 and a second layer 4 and between the second layer 4 and a third layer 5. In addition, FIGS. 5, 6, and 7 respectively illustrate the images of Example Nos. 1, 2, and 4, and show that, as the amount of alloy elements added increases in the order of Nos. 1, 2, and 4, the region of the reaction layer becomes wider.

### Experiment 2 (Evaluation of Wiring Resistance)

Each sample was produced in the same manner as in Experiment 1 described above except that a line-and-space pattern with a width of 100 μm and a length of 10 was formed. In this Experiment, a sputtering system in which the distance between electrodes was set to 100 mm instead of 55 mm, which was a normal distance, was used. Therefore, the amount of gas components, mainly oxygen, nitrogen, and water, that remain in a sputtering chamber and are taken into the film in this Experiment was larger than that in the case of film formation performed when the distance between electrodes was 55 mm The electrical resistivity in this Experiment was about 20% higher than that in the case of film formation performed when the distance between electrodes was 55 mm.

The electrical resistivity of the second layer in the obtained laminate wiring was measured by 4-terminal sensing, and the wiring resistance was evaluated. Given that wiring resistance was a parallel resistance of Mo and Al, and the resistivity of Mo was a parallel resistivity of 12 μΩcm before and after a heat treatment, the electrical resistivity of the Al alloy was calculated by subtracting the resistance of Mo, which was distributed in accordance with the film thickness ratio in the laminate wiring, from the wiring resistance. For reference, the electrical resistivity of the second layer at 24° C. before the heat treatment was measured similarly (“asdepo” column in Table). In this Experiment, samples with an electrical resistivity of 5.5 μΩcm or less were evaluated to have desired wiring resistance and were rated acceptable, and samples with an electrical resistivity of more than 5.5 μΩcm were evaluated to have high wiring resistance and were rated unacceptable.

TABLE 2

| | | Electrical resistivity (μΩcm) | | |
|---|---|---|---|---|
| No. | First layer/Second layer/Third layer | asdepo | 400° C. | 450° C. |
| 1 | Mo/Al/Mo | 3.7 | 4.2 | 4.6 |
| 2 | Mo/Al•0.02 at % Ni•0.035 at % | 4.3 | 4.7 | 4.9 |
| | La/Mo | | | |
| 3 | Mo/Al•0.04 at % Ni•0.07 at % | 4.7 | 5.4 | 5.5 |
| | La/Mo | | | |
| 4 | Mo/Al•0.08 at % Ni•0.14 at % | 5.3 | 6.6 | 7.9 |
| | La/Mo | | | |

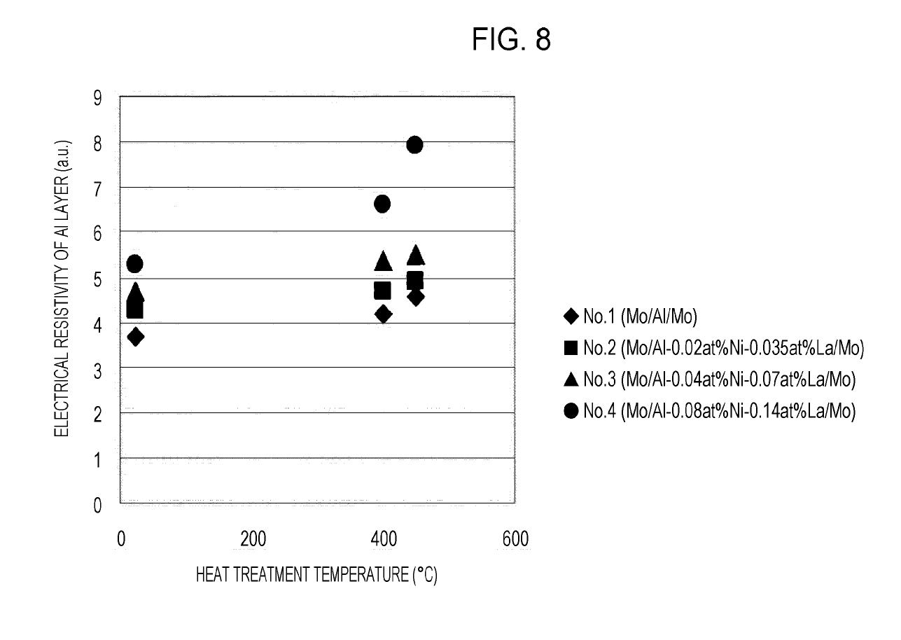

These results are shown in FIG. 8. FIG. 8 indicates that, when Example Nos. 1 to 3 were used, the electrical resistivity was as low as 5.5 μΩcm or less at both heating temperatures of 400° C. and 450° C.

Specifically, the electrical resistivity of Example No. 1 (black diamonds in Figure) containing pure Al in the second layer tended to increase as the heating temperature increased. However, the degree of increase in electrical resistivity was very small.

The electrical resistivity of Example Nos. 2 and 3 (black squares and black triangles in Figure) containing, in the second layer, the Al alloys that satisfied the requirements of the present invention also tended to increase as the heating temperature increased. However, the electrical resistivity of Example Nos. 2 and 3 was within the acceptable range. The degree of increase in electrical resistivity was larger than that in the case of pure Al.

Example No. 4 (black circles in Figure) was an example sample in which the total amount of alloy elements contained in the Al-alloy film, which was the second layer, was as large as 0.22 at %, and the electrical resistivity of Example No. 4 increased.

The results of Experiments 1 and 2 described above indicate that, when the wiring films of Example Nos. 2 and 3 containing the Al alloys defined in the present invention were used, an increase in wiring resistance was suppressed and no side hillocks or other defects were formed even after the wiring films were subjected to a thermal history at a high temperature of 400° C. or higher and 500° C. or lower, providing flat panel displays having high heat resistance.

The electrical resistivity of Example No. 1 containing pure Al after the heat treatment tended to gradually increase when the heating temperature exceeded 400° C. However, the degree of increase in electrical resistivity was very small. However, the heat resistance was low when pure Al was used. When pure Al was used, side hillocks were formed after the heat treatment.

Example No. 4 was an example sample including, in the second layer, an Al alloy containing an excess amount of alloy elements. In Example No. 4, no side hillocks were formed in the heat treatment and the heat resistance was good. However, FIG. 8 indicates that the electrical resistivity after the heat treatment significantly increased when the heating temperature exceeded 400° C. The degree of increase in electrical resistivity was much larger than that in the case of pure Al.

### REFERENCE SIGNS LIST

1 Protrusion corresponding to side hillock

2 Reaction layer

3 First layer

4 Second layer

5 Third layer

1. A wiring film having a laminate structure for a flat panel display which is formed on a substrate, the wiring film comprising:
a first layer comprising at least one high-melting-point metal selected from the group consisting of Mo, Ti, Cr, W, and Ta; and
a second layer comprising an Al alloy that contains:
a rare earth element in an amount of 0.01 at % or more and less than 0.2 at %, and
at least one of Ni and Co in an amount of 0.01 at % or more and less than 0.2 at %.

2. The wiring film for a flat panel display according to claim 1, further comprising a reaction layer at an interface between the first layer and the second layer, the reaction layer including Al and at least one of the high-melting-point metals.

3. (canceled)

4. The wiring film for a flat panel display according to claim 2, wherein the reaction layer is formed by a thermal history at 400° C. or higher and 500° C. or lower.

5. The wiring film for a flat panel display according to claim 1, wherein the rare earth elements include at least one selected from the group consisting of Nd, La, Gd, Dy, Y, and Ce.

6. The wiring film for a flat panel display according to claim 2, wherein the reaction layer includes a compound of Al and Mo.

7. The wiring film for a flat panel display according to claim 1, wherein the wiring film has a laminate structure in which the first layer and the second layer are formed in this order from a substrate side, or the wiring film has a laminate structure in which the second layer and the first layer are formed in this order from the substrate side.

8. The wiring film for a flat panel display according to claim 1, wherein the wiring film has a laminate structure in which the first layer, the second layer, and the first layer are formed in this order from a substrate side, and each of the reaction layers including Al and at least one of the high-melting-point metals is formed at each interface between the first layer and the second layer.
